(19) United States
(12) Patent Application Publication
(10) Pub. No.: US 2019/0212368 A1
(43) Pub. Date: Jul. 11, 2019

(54) PROBE CARD

(71) Applicant: MPI Corporation, Hsinchu County (TW)

(72) Inventors: Hsien-Ta HSU, Hsinchu County (TW); Yu-Chen HSU, Hsinchu County (TW); Ching-Hua WU, Hsinchu County (TW); Kuan-Chun CHOU, Hsinchu County (TW); Horng-Kuang FAN, Hsinchu County (TW)

(21) Appl. No.: 16/239,553

(22) Filed: Jan. 4, 2019

Related U.S. Application Data
(60) Provisional application No. 62/613,780, filed on Jan. 5, 2018.

(30) Foreign Application Priority Data
Jul. 13, 2018 (TW) 107124356

(51) Int. Cl. G01R 1/073

(52) U.S. Cl. CPC G01R 1/07378; G01R 1/07342

(57) ABSTRACT

A probe card includes a space transformer, a printed circuit board and a plurality of welding elements. The space transformer is disposed with a plurality of first conductive protrusions. Each of the first conductive protrusions has a first end surface. The printed circuit board is disposed with a plurality of second conductive protrusions. Each of the second conductive protrusions has a second end surface. The welding elements are respectively and electrically connected between each of the second end surfaces and the corresponding first end surface. A first surface of the space transformer away from the printed circuit board has a first degree of flatness. A second surface of the printed circuit board away from the space transformer has a second degree of flatness. The first degree of flatness is less than the second degree of flatness.

### RELATED APPLICATIONS

This application claims priority to U.S. Provisional Application Ser. No. 62/613,780, filed Jan. 5, 2018, and Taiwanese Application Serial Number 107124356, filed Jul. 13, 2018, which are herein incorporated by reference.

### BACKGROUND

### Technical Field

The present disclosure relates to probe cards.

### Description of Related Art

The main function of a probe card is to directly contact with the welding pads or bumps on a device under test (such as a wafer not yet packaged, a chip or a die) with its probe, in order to achieve the purpose of testing the device under test with the configuration of a testing machine or software control, such that defective products can be screened. In general, a testing signal is generated from the testing machine, and the testing signal reaches the device under test through the probe card. Afterwards, a signal of testing result is transmitted back to the testing machine through the probe card for analysis.

Therefore, a stable electrical performance of a probe card is undoubtedly an important issue in the industry.

### SUMMARY

A technical aspect of the present disclosure is to provide a probe card, which can securely fix the space transformer and the printed circuit board, thus improving the stability of the end product.

According to an embodiment of the present disclosure, a probe card includes a space transformer, a printed circuit board and a plurality of welding elements. The space transformer is disposed with a plurality of first conductive protrusions. Each of the first conductive protrusions has a first end surface. The printed circuit board is disposed with a plurality of second conductive protrusions. Each of the second conductive protrusions has a second end surface. The welding elements are respectively and electrically connected between each of the second end surfaces and the corresponding first end surface. A first surface of the space transformer away from the printed circuit board has a first degree of flatness. A second surface of the printed circuit board away from the space transformer has a second degree of flatness. The first degree of flatness is less than the second degree of flatness.

In one or more embodiments of the present disclosure, the first surface has a first height difference defining the first degree of flatness. The second surface has a second height difference defining the second degree of flatness.

In one or more embodiments of the present disclosure, at least two of the first end surfaces have different distances from the space transformer.

In one or more embodiments of the present disclosure, at least two of the second end surfaces have different distances from the printed circuit board.

In one or more embodiments of the present disclosure, each of the first conductive protrusions includes a base portion and a protruding portion. The base portion is connected with the space transformer. The base portion has a supporting surface away from the space transformer. The protruding portion has a third end surface opposite to the first end surface. The third end surface connects with the supporting surface. An area of the supporting surface is larger than an area of the third end surface.

In one or more embodiments of the present disclosure, an area of the first end surface is same as the area of the third end surface.

In one or more embodiments of the present disclosure, an area of the first end surface is less than the area of the third end surface.

In one or more embodiments of the present disclosure, the probe card further includes a solder mask. The solder mask is located on the space transformer and at least partially covers the base portion.

In one or more embodiments of the present disclosure, the probe card further includes a dielectric layer. The dielectric layer is located on a side of the solder mask away from the space transformer, in which at least one of the protruding portions is embedded in the dielectric layer to form a concave structure.

In one or more embodiments of the present disclosure, the probe card further includes a dielectric layer. The dielectric layer is located on a side of the solder mask away from the space transformer. Each of the protruding portions further includes a first subsidiary protruding portion and a second subsidiary protruding portion. The third end surface is located on the first subsidiary protruding portion. The first subsidiary protruding portion is at least partially coated by the dielectric layer. The second subsidiary protruding portion is connected with an end of the first subsidiary protruding portion away from the third end surface. The first end surface is located on the second subsidiary protruding portion. The second subsidiary protruding portion is exposed from the dielectric layer.

In one or more embodiments of the present disclosure, the dielectric layer has a through hole to expose at least a portion of the space transformer. The probe card further includes an electronic element. The electronic element is disposed on the space transformer and located within the through hole. The space transformer has a groove. The groove is communicated with the through hole. The electronic element is disposed within the groove.

According to another embodiment of the present disclosure, a probe card includes a space transformer, a probe head and a printed circuit board. The space transformer includes a lower structure and an upper structure. The lower structure has a first surface. The upper structure is electrically connected with the lower structure. The upper structure has a second surface away from the lower structure. The first surface is away from the upper structure. The probe head is electrically connected with the first surface. The upper structure is located between the printed circuit board and the lower structure. The first surface has a first height difference. The second surface has a second height difference. The first height difference is less than the second height difference.

In one or more embodiments of the present disclosure, the upper structure is multi-layered organic (MLO) or multi-layered ceramic (MLC) and the lower structure is multi-layered organic.

In one or more embodiments of the present disclosure, the first height difference defines a first degree of flatness. The second height difference defines a second degree of flatness. The first degree of flatness is less than the second degree of flatness.

In one or more embodiments of the present disclosure, the upper structure is disposed with a plurality of first conductive protrusions. The first conductive protrusions face to the lower structure. Each of the first conductive protrusions has a first end surface away from the second surface. At least two of the first end surfaces have different distances from the second surface.

In one or more embodiments of the present disclosure, the lower structure is disposed with a plurality of second conductive protrusions. Each of the second conductive protrusions has a second end surface. The second end surface is electrically connected with the corresponding first end surface. At least two of the second end surfaces have different distances from the first surface.

In one or more embodiments of the present disclosure, the probe card further includes a plurality of welding elements. The welding elements are respectively welded and electrically connected between each of the second end surfaces and the corresponding first end surface.

In one or more embodiments of the present disclosure, each of the first conductive protrusions includes a base portion and a protruding portion. The base portion is connected with the upper structure. The base portion has a supporting surface away from the upper structure. The protruding portion has a third end surface opposite to the first end surface. The third end surface connects with the supporting surface. An area of the supporting surface is larger than an area of the third end surface.

### BRIEF DESCRIPTION OF THE DRAWINGS

The disclosure can be more fully understood by reading the following detailed description of the embodiments, with reference made to the accompanying drawings as follows:

FIG. 1 is a cross-sectional view of a probe card according to an embodiment of the present disclosure;

FIG. 2 is a locally magnified cross-sectional view of a probe card according to another embodiment of the present disclosure;

FIG. 3 is a magnified cross-sectional view of a first conductive protrusion according to a further embodiment of the present disclosure;

FIG. 4 is a locally magnified cross-sectional view of a probe card according to another embodiment of the present disclosure;

FIG. 5 is a locally magnified cross-sectional view of a probe card according to a further embodiment of the present disclosure;

FIG. 6 is a locally magnified cross-sectional view of a probe card according to another embodiment of the present disclosure;

FIG. 7 is a locally magnified cross-sectional view of a probe card according to a further embodiment of the present disclosure;

FIG. 8 is a side view of a probe card according to another embodiment of the present disclosure; and

FIG. 9 is a side view of a probe card according to a further embodiment of the present disclosure.

### DETAILED DESCRIPTION

Drawings will be used below to disclose embodiments of the present disclosure. For the sake of clear illustration, many practical details will be explained together in the description below. However, it is appreciated that the practical details should not be used to limit the claimed scope. In other words, in some embodiments of the present disclosure, the practical details are not essential. Moreover, for the sake of drawing simplification, some customary structures and elements in the drawings will be schematically shown in a simplified way. Wherever possible, the same reference numbers are used in the drawings and the description to refer to the same or like parts.

Unless otherwise defined, all terms (including technical and scientific terms) used herein have the same meanings as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

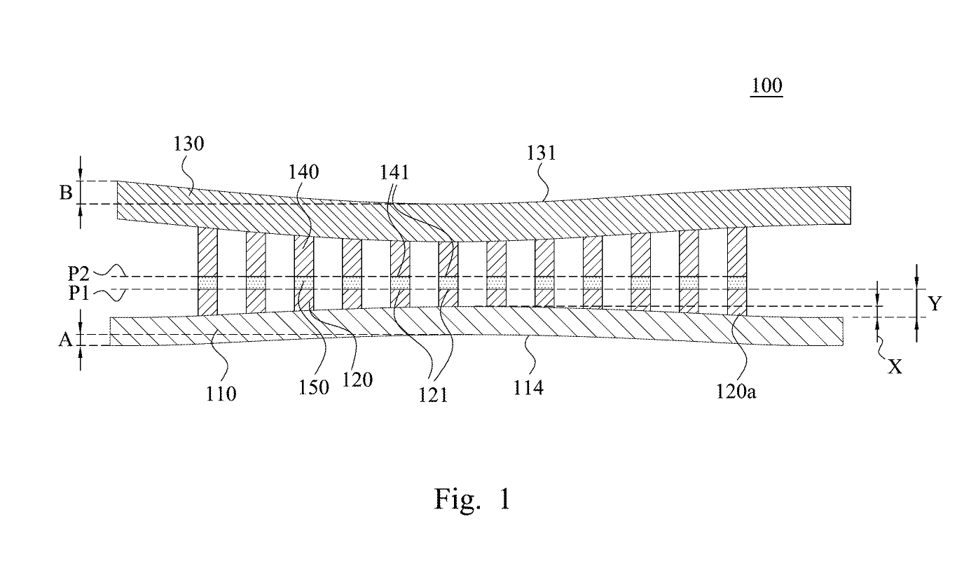

Reference is made to FIG. 1. FIG. 1 is a cross-sectional view of a probe card 100 according to an embodiment of the present disclosure. In this embodiment, as shown in FIG. 1, a probe card 100 includes a space transformer 110, a plurality of first conductive protrusions 120, a printed circuit board 130, a plurality of second conductive protrusions 140, and a plurality of welding elements 150. The first conductive protrusions 120 are connected to the space transformer 110. Each of the first conductive protrusions 120 has a first end surface 121 away from the space transformer 110. The first end surfaces 121 are substantially located on the same first horizontal plane P1. In practice, the first end surfaces 121 of the first conductive protrusions 120 can be formed by the method of polishing or cutting. Thus, the first end surfaces 121 are allowed with a tolerance in a magnitude of microns (μm). At least two of the first end surfaces 121 have different distances from the space transformer 110. The second conductive protrusions 140 are connected to the printed circuit board 130. Each of the second conductive protrusions 140 has a second end surface 141 away from the printed circuit board 130. The second end surfaces 141 are substantially located on the same second horizontal plane P2. Similarly, the second end surfaces 141 of the second conductive protrusions 140 can be formed by the method of polishing or cutting. Thus, the second end surfaces 141 are allowed with a tolerance in a magnitude of microns. At least two of the second end surfaces 141 have different distances from the printed circuit board 130. The second end surfaces 141 of the second conductive protrusions 140 and the first end surfaces 121 of the first conductive protrusions 120 face to each other and are parallel with each other. That is, the first horizontal plane P1 and the second horizontal plane P2 are parallel with each other. The second conductive protrusions 140 and the first conductive protrusions 120 are substantially of the same structure. The welding elements 150 are respectively and electrically connected between each of the second end surfaces 141 and the corresponding first end surface 121.

Furthermore, a first surface 114 of the space transformer 110 away from the printed circuit board 130 has a first degree of flatness. A second surface 131 of the printed circuit board 130 away from the space transformer 110 has a second degree of flatness. The first degree of flatness is less than the second degree of flatness. In other words, the first surface 114 of the space transformer 110 is flatter than the second surface 131 of the printed circuit board 130.

In addition, the first surface 114 of the space transformer 110 has a first height difference A. The first height difference A defines the first degree of flatness of the first surface 114. The first height difference A can be a distance between the highest point and the lowest point of the first surface 114. Thus, the smaller the first height difference A, the flatter the first surface 114 and the smaller the first degree of flatness will be. On the contrary, the second surface 131 of the printed circuit board 130 has a second height difference B. The second height difference B defines the second degree of flatness of the second surface 131. The second height difference B can be a distance between the highest point and the lowest point of the second surface 131. Thus, the smaller the second height difference B, the flatter the second surface 131 and the smaller the second degree of flatness will be. In this embodiment, the first height difference A is smaller than the second height difference B. That is, as mentioned above, the first surface 114 of the space transformer 110 is flatter than the second surface 131 of the printed circuit board 130, and the first degree of flatness of the first surface 114 is smaller than the second degree of flatness of the second surface 131.

To be specific, even if the printed circuit board 130 appears with the condition of warp, i.e., the second degree of flatness of the second surface 131 is poor, through the compensation by the different heights of the first conductive protrusions 120 and the second conductive protrusions 140 to the warp of the printed circuit board 130, the effect of the warped printed circuit board 130 to the flatness of the space transformer 110 is effectively reduced. In this way, the first surface 114 of the space transformer 110 can be flatter than the second surface 131 of the printed circuit board 130. That is, as mentioned above, the first height difference A of the first surface 114 is smaller than the second height difference B of the second surface 131, and the first degree of flatness of the first surface 114 is smaller than the second degree of flatness of the second surface 131.

On the other hand, even if the space transformer 110 and/or the printed circuit board 130 appears with the condition of warp, since the second end surfaces 141 of the second conductive protrusions 140 and the first end surfaces 121 of the first conductive protrusions 120 face to each other and are parallel with each other, the welding elements 150 can be evenly connected between the second end surfaces 141 and the first end surfaces 121. Thus, the space transformer 110 and the printed circuit board 130 can be securely fixed, improving the stability of the end product. To be more specific, for the welding elements 150 located between the second end surfaces 141 and the first end surfaces 121, the consistency of volume can be effectively controlled. In practical applications, the welding elements 150 can be solder, which joints the second conductive protrusions 140 and the first conductive protrusions 120 during the reflow process. However, this does not intend to limit the present disclosure.

In other words, the warp condition of the space transformer 110 and the printed circuit board 130 are respectively compensated by the first conductive protrusions 120 of different heights and the second conductive protrusions 140 of different heights. Therefore, the connection between the space transformer 110 and the printed circuit board 130 is not affected by the warp condition of the space transformer 110 and/or the printed circuit board 130.

In practical applications, taking the space transformer 110 as an example, the heights of the first conductive protrusions 120 should be larger than or equal to the degree of warp of the space transformer 110. In this way, the warp of the space transformer 110 can be compensated by the first conductive protrusions 120. As shown in FIG. 1, if the degree of warp of the space transformer 110 is X, and the height of the highest first conductive protrusion 120 (as the first conductive protrusion 120a in FIG. 1) is Y, then Y is larger than X by at least 5 μm. For example, if the degree of warp of the space transformer 110 is 50 μm, then the minimum value of the height of the highest first conductive protrusion 120 is 55 μm.

Similarly, for the warp of the printed circuit board 130 to be compensated by the second conductive protrusions 140, the heights of the second conductive protrusions 140 should be larger than or equal to the degree of warp of the printed circuit board 130. In practical applications, since the dimensions of the printed circuit board 130 is larger than the space transformer 110, the degree of warp of the printed circuit board 130 may be larger than the degree of warp of the space transformer 110. When the degree of warp of the printed circuit board 130 is obviously larger than the degree of warp of the space transformer 110, the user can use only the second conductive protrusions 140 of different heights, but not the first conductive protrusions 120 of different heights, to compensate the warp of the printed circuit board 130, according to the actual situation.

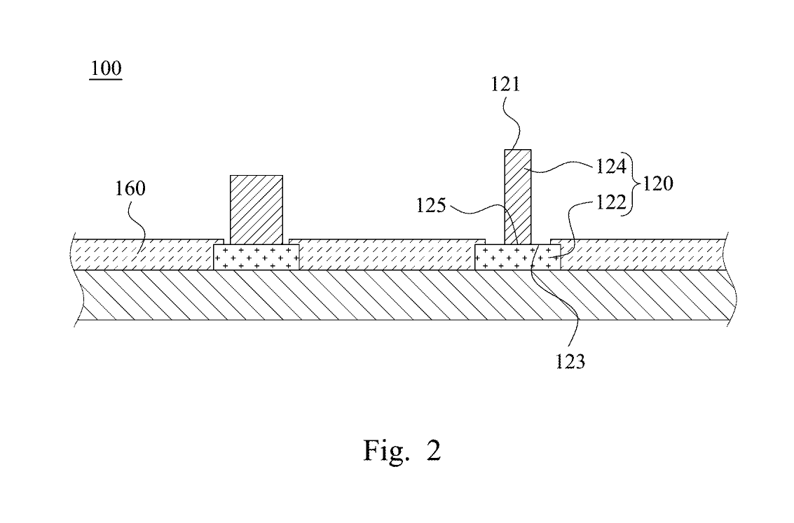

Reference is made to FIG. 2. FIG. 2 is a locally magnified cross-sectional view of a probe card 100 according to another embodiment of the present disclosure. In this embodiment, as shown in FIG. 2, each of the first conductive protrusions 120 includes a base portion 122 and a protruding portion 124. The base portion 122 is connected with the space transformer 110. The base portion 122 has a supporting surface 123. The supporting surface 123 is away from the space transformer 110. The protruding portion 124 has the first end surface 121 and a third end surface 125 opposite to each other. The third end surface 125 connects with the supporting surface 123. An area of the supporting surface 123 is larger than an area of the third end surface 125.

Furthermore, according to the actual situation, the material of the protruding portion 124 can be copper, copper-silver alloy, nickel-palladium alloy and nickel-cobalt alloy etc. However, this does not intend to limit the present disclosure.

In addition, the protruding portion 124 can be in the shape of a circular column, a square column or a rectangular column etc. The height of the protruding portion 124 can be smaller than the width of the first end surface 121. For example, the height of the protruding portion 124 can be about 150 μm, while the width of the first end surface 121 can be 180 μm. However, in other embodiments, the height of the protruding portion 124 can be larger than the width of the first end surface 121.

Furthermore, as shown in FIG. 2, the probe card 100 further includes a solder mask 160. The solder mask 160 is located on the space transformer 110 and at least partially covers the base portions 122 of the first conductive protrusions 120.

In this embodiment, as shown in FIG. 2, an area of the first end surface 121 is the same as the area of the third end surface 125, such that the first conductive protrusion 120 forms a columnar shape, such as a circular column, a square column or a rectangular column etc.

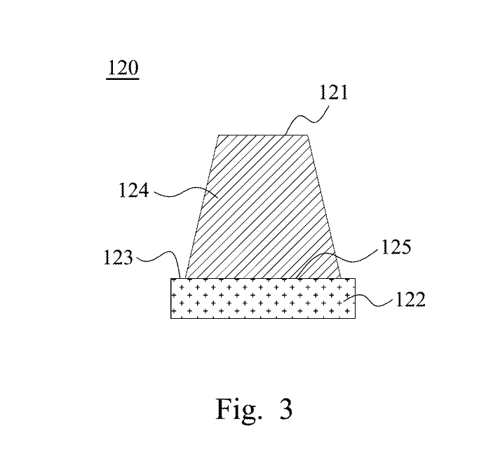

Reference is made to FIG. 3. FIG. 3 is a magnified cross-sectional view of a first conductive protrusion 120 according to a further embodiment of the present disclosure. In this embodiment, as shown in FIG. 3, the area of the first end surface 121 of the first conductive protrusion 120 is less than the area of the third end surface 125, such that the first conductive protrusion 120 forms a cone shape with a narrow top and a wide bottom.

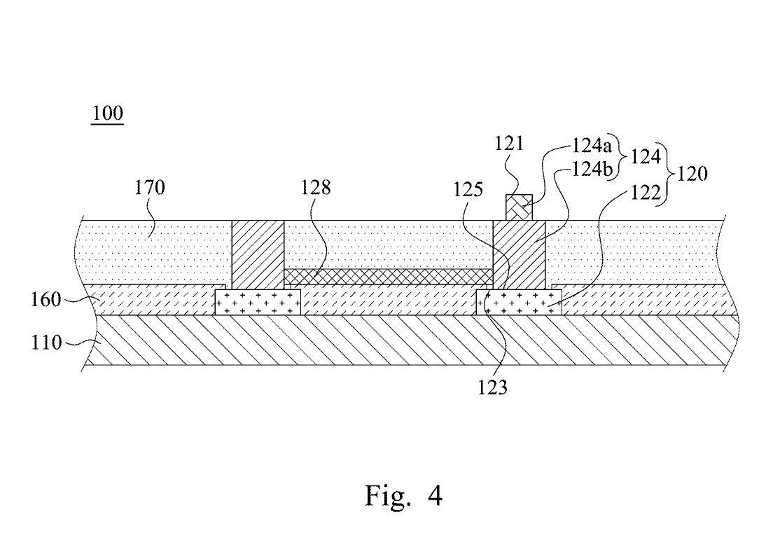

Reference is made to FIG. 4. FIG. 4 is a locally magnified cross-sectional view of a probe card 100 according to another embodiment of the present disclosure. In this embodiment, the probe card 100 further includes a dielectric layer 170. As shown in FIG. 4, the dielectric layer 170 is located on a side of the solder mask 160 away from the space transformer 110. Moreover, each of the protruding portions 124 further includes a first subsidiary protruding portion 124a and a second subsidiary protruding portion 124b. The third end surface 125 is located on the second subsidiary protruding portion 124b. The second subsidiary protruding portion 124b is at least partially coated by the dielectric layer 170. Through the cover of the second subsidiary protruding portion 124b by the dielectric layer 170, the chance of oxidation of the second subsidiary protruding portion 124b is reduced, and the overall structural strength of the protruding portions 124 and the space transformer 110 is strengthened. Moreover, the first subsidiary protruding portion 124a is connected with an end of the second subsidiary protruding portion 124b away from the third end surface 125. The first end surface 121 is located on the first subsidiary protruding portion 124a. The first subsidiary protruding portion 124a is exposed from the dielectric layer 170, facilitating the mutual connection with the welding element 150 (not shown in FIG. 4, please refer to FIG. 1). In this embodiment, the overall height of the solder mask 160, the dielectric layer 170 and the first subsidiary protruding portion 124a is larger than the degree of warp X of the space transformer 110 as mentioned above.

Furthermore, the probe card 110 further includes a circuit 128. As shown in FIG. 4, the circuit 128 is located in the dielectric layer 170, and is electrically connected with the second subsidiary protruding portion 124b and the base portion 122.

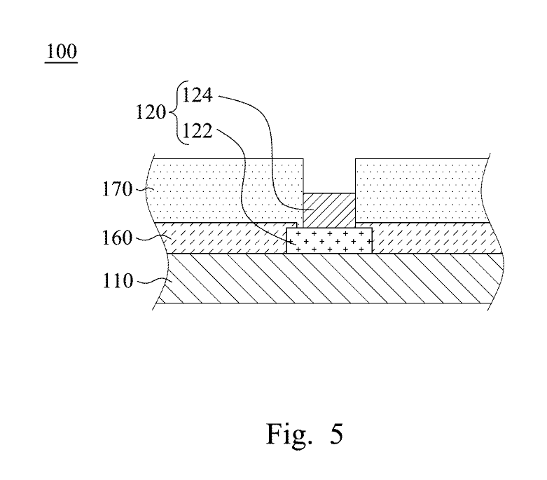

Reference is made to FIG. 5. FIG. 5 is a locally magnified cross-sectional view of a probe card 100 according to a further embodiment of the present disclosure. In this embodiment, as shown in FIG. 5, the protruding portion 124 of the first conductive protrusion 120 can be embedded in the dielectric layer 170, such that the dielectric layer 170 is higher than the protruding portion 124 to form a concave structure. In practical applications, the concave structure formed by the dielectric layer 170 and the protruding portion 124 is configured to accommodate a low-temperature solder in the subsequent manufacturing process.

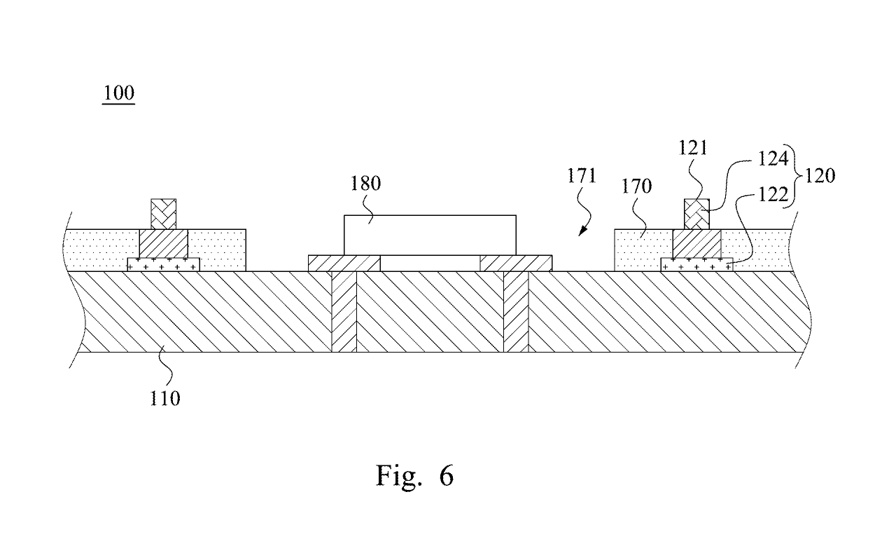

Reference is made to FIG. 6. FIG. 6 is a locally magnified cross-sectional view of a probe card 100 according to another embodiment of the present disclosure. In this embodiment, as shown in FIG. 6, the dielectric layer 170 has a through hole 171 to expose at least a portion of the space transformer 110. The probe card 100 further includes an electronic element 180. The electronic element 180 is disposed on the space transformer 110 and located within the through hole 171. For example, the electronic element 180 can be a capacitor. However, this does not intend to limit the present disclosure. It is worth to note that the first conductive protrusions 120 are higher than the electronic element 180. In other words, the first end surfaces 121 of the first conductive protrusions 120 are farther away from the space transformer 110 than the electronic element 180. In this way, through setting the heights of the first conductive protrusions 120 and the second conductive protrusions 140 (not shown in FIG. 6, please see FIG. 1), a space can be provided for installing the electronic element 180, thus increasing the electrical performance of the probe card 100.

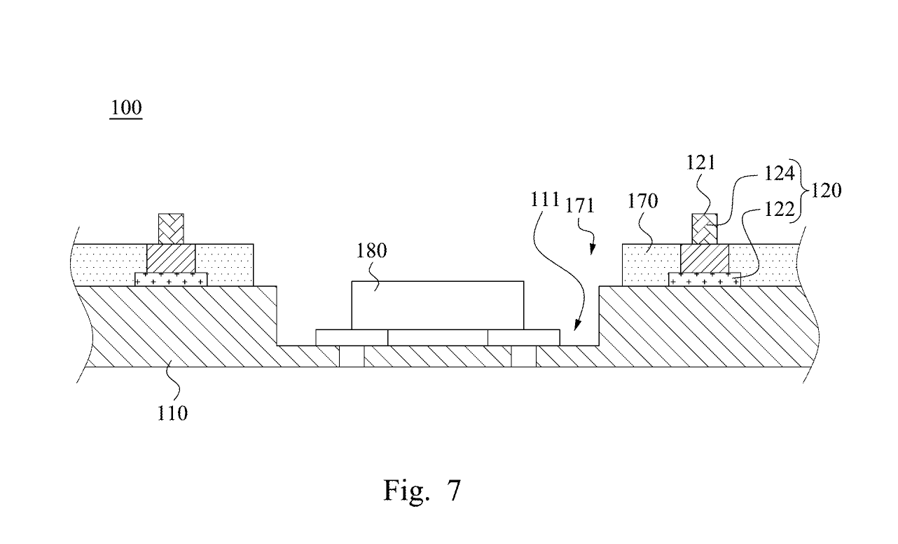

Reference is made to FIG. 7. FIG. 7 is a locally magnified cross-sectional view of a probe card 100 according to a further embodiment of the present disclosure. In this embodiment, as shown in FIG. 7, the space transformer 110 has a groove 111. The groove 111 is communicated with the through hole 171 of the dielectric layer 170. The electronic element 180 is disposed within the groove 111, such that the electronic element 180 is further lower than the first end surfaces 121 of the first conductive protrusions 120.

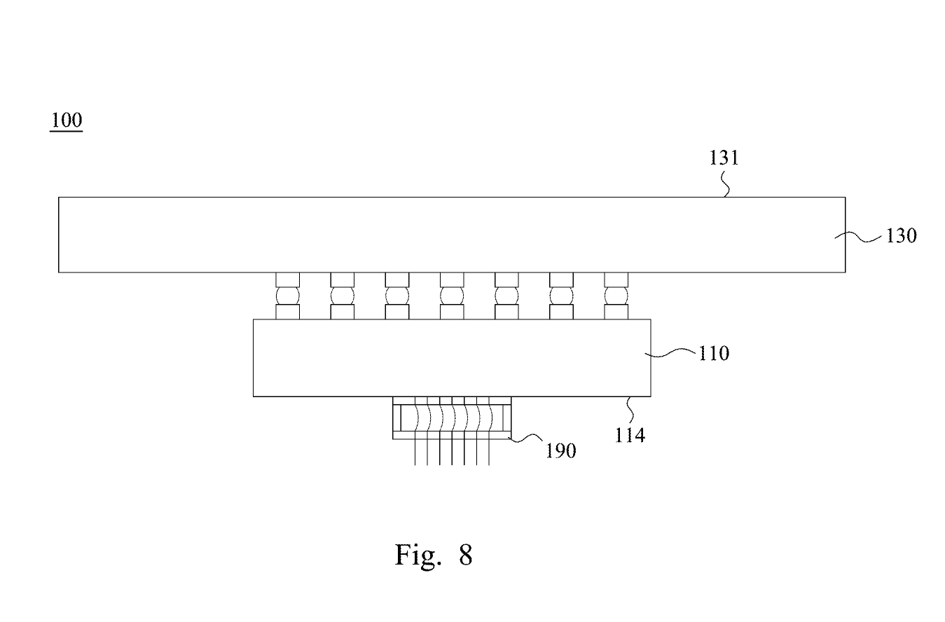

Reference is made to FIG. 8. FIG. 8 is a side view of a probe card 100 according to another embodiment of the present disclosure. In this embodiment, as shown in FIG. 8, the probe card 100 further includes a probe head 190. The probe head 190 is located on the first surface 114 of the space transformer 110. This means that the space transformer 110 is located between the printed circuit board 130 and the probe head 190. In addition, the probe head 190 is electrically connected with the space transformer 110. As mentioned above, since the first surface 114 of the space transformer 110 is flatter than the second surface 131 of the printed circuit board 130, the connection between the probe head 190 and the space transformer 110 becomes more reliable, and the electrical reliability can be improved. When the probe card 100 is used to test the device under test, the amount of over drive does not need to be too heavy in order to achieve a stable electrical reliability. Thus, the working life of the probe card 100 can be increased.

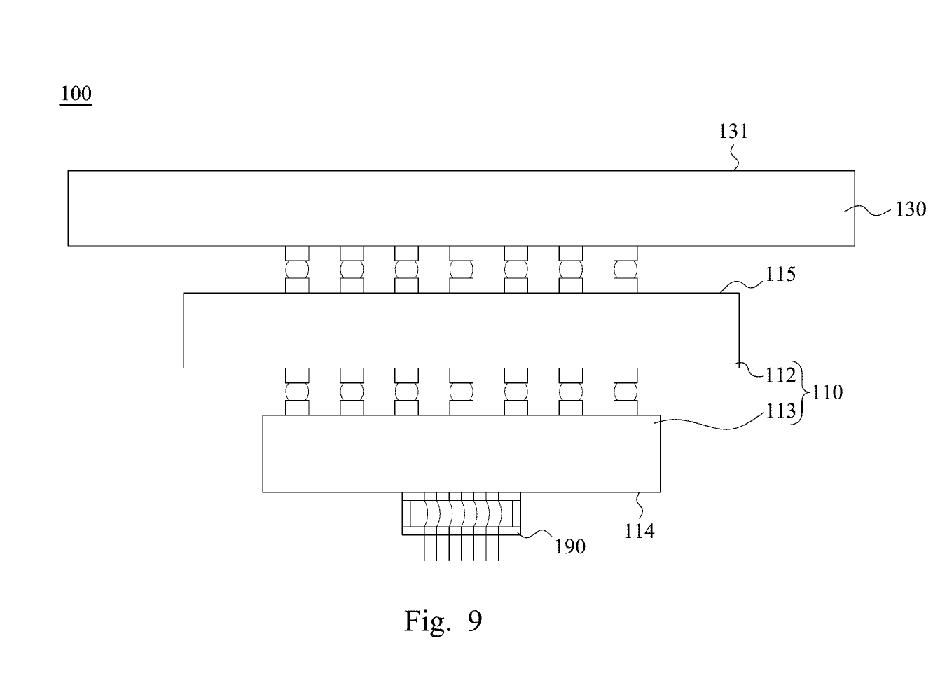

Reference is made to FIG. 9. FIG. 9 is a side view of a probe card 100 according to a further embodiment of the present disclosure. Furthermore, as shown in FIG. 9, the space transformer 110 includes an upper structure 112 and a lower structure 113. To be specific, the upper structure 112 is located between the printed circuit board 130 and the lower structure 113. The upper structure 112 and the lower structure 113 are electrically connected to each other, such as using the welding material to reflow. The lower structure 113 has the first surface 114 away from the upper structure 112. The upper structure 112 has a second surface 115 away from the lower structure 113. The first surface 114 has a first height difference. The second surface 115 has a second height difference. In this embodiment, the first height difference is less than the second height difference. This means the first surface 114 of the lower structure 113 is flatter than the second surface 115 of the upper structure 112. The probe head 190 is electrically connected with the lower structure 113. For example, the probe tail of the probe on the probe head 190 contacts with the protruding portion on the first surface 114 of the lower structure 113 by the manner of contacting. The probe head 190 is configured to carry out an electrical connection with the device under test (not shown), in order to carry out a test of electrical signal to the device under test. To be specific, the way of electrical connection between the upper structure 112 and the lower structure 113 can take reference to the way of connection between the printed circuit board 130 and the space transformer 110 as mentioned above. Therefore, even if the upper structure 112 and/or the lower structure 113 appear with the condition of warp, the connection between the upper structure 112 and the lower structure 113 is not affected by the warp condition of the upper structure 112 and/or the lower structure 113.

In practical applications, for example, the upper structure 112 can be multi-layered organic (MLO) or multi-layered ceramic (MLC). The lower structure 113 can be multi-layered organic.

In summary, when compared with the prior art, the embodiments of the present disclosure mentioned above have at least the following advantages:

(1) Even if the printed circuit board appears with the condition of warp, i.e., the second degree of flatness of the second surface is poor, through the compensation by the different heights of the first conductive protrusions and the second conductive protrusions to the warp of the printed circuit board, the effect of the warped printed circuit board to the flatness of the space transformer is effectively reduced. In this way, the first surface of the space transformer can be flatter than the second surface of the printed circuit board.

(2) Even if the space transformer and/or the printed circuit board appears with the condition of warp, since the second end surfaces of the second conductive protrusions and the first end surfaces of the first conductive protrusions face to each other and are parallel with each other, the welding elements can be evenly connected between the second end surfaces and the first end surfaces. Thus, the space transformer and the printed circuit board can be securely fixed, improving the stability of the end product.

(3) Since the warp condition of the space transformer and the printed circuit board are respectively compensated by the first conductive protrusions of different heights and the second conductive protrusions of different heights, the connection between the space transformer and the printed circuit board is not affected by the warp condition of the space transformer and/or the printed circuit board.

(4) Through setting the heights of the first conductive protrusions and the second conductive protrusions, a space can be provided for installing the electronic element, thus increasing the electrical performance of the probe card.

Although the present disclosure has been described in considerable detail with reference to certain embodiments thereof, other embodiments are possible. Therefore, the spirit and scope of the appended claims should not be limited to the description of the embodiments contained herein.

It will be apparent to the person having ordinary skill in the art that various modifications and variations can be made to the structure of the present disclosure without departing from the scope or spirit of the present disclosure. In view of the foregoing, it is intended that the present disclosure cover modifications and variations of the present disclosure provided they fall within the scope of the following claims.

What is claimed is:

1. A probe card, comprising:
a space transformer disposed with a plurality of first conductive protrusions, each of the first conductive protrusions having a first end surface;
a printed circuit board disposed with a plurality of second conductive protrusions, each of the second conductive protrusions having a second end surface; and
a plurality of welding elements respectively and electrically connected between each of the second end surfaces and the corresponding first end surface,
wherein a first surface of the space transformer away from the printed circuit board has a first degree of flatness, a second surface of the printed circuit board away from the space transformer has a second degree of flatness, the first degree of flatness is less than the second degree of flatness.

2. The probe card of claim 1, wherein the first surface has a first height difference defining the first degree of flatness, the second surface has a second height difference defining the second degree of flatness.

3. The probe card of claim 1, wherein at least two of the first end surfaces have different distances from the space transformer.

4. The probe card of claim 1, wherein at least two of the second end surfaces have different distances from the printed circuit board.

5. The probe card of claim 1, wherein each of the first conductive protrusions comprises:
a base portion connected with the space transformer, the base portion has a supporting surface away from the space transformer; and
a protruding portion having a third end surface opposite to the first end surface, the third end surface connects with the supporting surface, an area of the supporting surface is larger than an area of the third end surface.

6. The probe card of claim 5, wherein an area of the first end surface is same as the area of the third end surface.

7. The probe card of claim 5, wherein an area of the first end surface is less than the area of the third end surface.

8. The probe card of claim 5, further comprising:
a solder mask located on the space transformer and at least partially covering the base portion.

9. The probe card of claim 8, further comprising:
a dielectric layer located on a side of the solder mask away from the space transformer, wherein at least one of the protruding portions is embedded in the dielectric layer to form a concave structure.

10. The probe card of claim 8, further comprising:
a dielectric layer located on a side of the solder mask away from the space transformer, each of the protruding portions further comprising:
a first subsidiary protruding portion, the third end surface being located on the first subsidiary protruding portion, the first subsidiary protruding portion being at least partially coated by the dielectric layer; and
a second subsidiary protruding portion connected with an end of the first subsidiary protruding portion away from the third end surface, the first end surface being located on the second subsidiary protruding portion, the second subsidiary protruding portion being exposed from the dielectric layer.

11. The probe card of claim 10, wherein the dielectric layer has a through hole to expose at least a portion of the space transformer, the probe card further comprises an electronic element disposed on the space transformer and located within the through hole, the space transformer has a groove communicated with the through hole, the electronic element is disposed within the groove.

12. A probe card, comprising:
a space transformer comprising:
a lower structure having a first surface; and
an upper structure electrically connected with the lower structure, the upper structure having a second surface away from the lower structure, the first surface being away from the upper structure;
a probe head electrically connected with the first surface; and
a printed circuit board, the upper structure being located between the printed circuit board and the lower structure,
wherein the first surface has a first height difference, the second surface has a second height difference, the first height difference is less than the second height difference.

13. The probe card of claim 12, wherein the upper structure is multi-layered organic (MLO) or multi-layered ceramic (MLC) and the lower structure is multi-layered organic.

14. The probe card of claim 12, wherein the first height difference defines a first degree of flatness, the second height difference defines a second degree of flatness, and the first degree of flatness is less than the second degree of flatness.

15. The probe card of claim 12, wherein the upper structure is disposed with a plurality of first conductive protrusions facing to the lower structure, each of the first conductive protrusions has a first end surface away from the second surface, at least two of the first end surfaces have different distances from the second surface.

16. The probe card of claim 15, wherein the lower structure is disposed with a plurality of second conductive protrusions, each of the second conductive protrusions having a second end surface electrically connected with the corresponding first end surface, at least two of the second end surfaces have different distances from the first surface.

17. The probe card of claim 16, further comprising:
a plurality of welding elements respectively welded and electrically connected between each of the second end surfaces and the corresponding first end surface.

18. The probe card of claim 15, wherein each of the first conductive protrusions comprises:
a base portion connected with the upper structure, the base portion has a supporting surface away from the upper structure; and
a protruding portion having a third end surface opposite to the first end surface, the third end surface connects with the supporting surface, an area of the supporting surface is larger than an area of the third end surface.
